(19) United States
(12) Patent Application Publication
(10) Pub. No.: US 2026/0150229 A1
(43) Pub. Date: May 28, 2026

(54) HEAT DISSIPATION MODULE AND FAN ASSEMBLY

(71) Applicant: PURPLE CLOUD DEVELOPMENT PTE. LTD., Singapore (SG)

(72) Inventor: Shiman XU, Hui Zhou City (CN)

(73) Assignee: PURPLE CLOUD DEVELOPMENT PTE. LTD., Singapore (SG)

(21) Appl. No.: 19/395,690

(22) Filed: Nov. 20, 2025

(30) Foreign Application Priority Data
Nov. 27, 2024 (CN) 202422909793.0

(51) Int. Cl. H05K 7/20

(52) U.S. Cl. CPC H05K 7/20172; H05K 7/20336; H05K 7/20409; H05K 7/20509

(57) ABSTRACT

A heat dissipation module includes a fan assembly and a securing device. The fan assembly includes a fan including a fan frame and a fan blade. The fan blade is rotatably disposed in the fan frame. The fan frame includes a first assembling portion and a second assembling portion and both of them are arranged along an axial direction of the fan blade. The fan assembly further includes a fastener that movably extends through the first assembling portion and the second assembling portion. The fan assembly also includes a stopper that is mounted into the fastener and located between the first assembling portion and the second assembling portion. The fastener extends through the first assembling portion and the second assembling portion and is fastened to the securing device.

### CROSS-REFERENCE TO RELATED APPLICATIONS

This application claims priority to Chinese Application No. 2024229097930, filed on November 27, 2024, which is incorporated herein by reference in its entirety.

### TECHNICAL FIELD

The present disclosure relates to a heat dissipation module and a fan assembly, and more particularly, to a heat dissipation module and a fan assembly provided with a fastening structure.

### BACKGROUND

With the rapid advancement of technology, the computing performance of electronic components has significantly increased, resulting in the generation of substantial heat. To protect electronic components from damage caused by excessive heat, a fan is generally installed in electronic devices to dissipate the heat generated by the components, thereby ensuring their operation remains within an acceptable temperature range.

A fan is typically installed in a liquid-cooling device or chassis to help dissipate heat from electronic components. For example, in a liquid-cooling device, the fan is usually secured by screws. The operator must first locate and gather the screws, and then tighten them using a hand tool before securing the fan to the mounting part. However, if the screws are missing or unavailable, this fastening process cannot be completed immediately, resulting in annoyance during the fan assembly. Therefore, improving the ease of fan assembling has emerged as a crucial priority for designers.

### SUMMARY

The present disclosure provides a heat dissipation module and a fan assembly that improve the convenience of assembling the fan assembly.

An aspect of the present disclosure provide a heat dissipation module. The heat dissipation module includes a fan assembly and a securing device. The fan assembly includes a fan having a fan frame and a fan blade. The fan blade is rotatably disposed in the fan frame that has a first assembling portion and a second assembling portion. Both of the first assembling portion and the second assembling portion are arranged along an axial direction of the fan blade. The fan assembly also includes a fastener that movably extends through the first assembling portion and the second assembling portion. The fan assembly further includes a stopper that is disposed on the fastener and is located between the first assembling portion and the second assembling portion.

In some embodiments, the first assembling portion and the second assembling portion are located at corner portions of the fan frame. In some embodiments, the fastener includes a head, a first fastening portion, and a connecting portion, the head and the first fastening portion being connected to opposite ends of the connecting portion. In some embodiments, the head has a diameter greater than each of diameters of the first fastening portion and the connecting portion. In some embodiments, the head abuts against the first assembling portion, and the first fastening portion passes through the second assembling portion to be fastened to the securing device. In some embodiments, the connecting portion is located at least partially between the first assembling portion and the second assembling portion, and the stopper is mounted into the connecting portion. In some embodiments, the connecting portion has an assembling groove located between the first assembling portion and the second assembling portion, and the stopper is mounted into the assembling groove. In some embodiments, the securing device includes a mounting frame, a heat pipe, and a fin set, the mounting frame being disposed adjacent to the fan frame, the first fastening portion being fastened to the mounting frame, the fin set being disposed on the heat pipe, and the heat pipe, along with the fin set, being located on a side of the mounting frame that face away from the fan frame. In some embodiments, the fin set and the fan assembly are arranged on opposite sides of the mounting frame. In some embodiments, the stopper surrounds an outer surface of the connecting portion. In some embodiments, the head of the fastener is positioned on an outer surface of the fan frame.

In some embodiments, the fastener is linearly aligned with the first assembling portion and the second assembling portion along the axial direction of the fan blade. In some embodiments, the securing device is a liquid cooling device.

Another aspect of the present disclosure provides a fan assembly configured to be installed to a liquid cooling device. The fan assembly includes a fan having a fan frame and a fan blade. The fan blade is rotatably disposed in the fan frame that includes a first assembling portion and a second assembling portion. Both of the first assembling portion and the second assembling portion are arranged along an axial direction of the fan blade. The fan assembly also includes a fastener that movably extends through the first assembling portion and the second assembling portion. The fan assembly further includes a stopper that is clamped into the fastener and located between the first assembling portion and the second assembling portion to retain the fastener within the fan frame.

In some embodiments, the first assembling portion and the second assembling portion are located at corner portions of the fan frame. In some embodiments, the fastener includes a head, a first fastening portion, and a connecting portion, the head and the first fastening portion being connected to opposite ends of the connecting portion. In some embodiments, the head abuts against the first assembling portion, and the first fastening portion passes through the second assembling portion to be fastened to the liquid cooling device.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Various embodiments of this disclosure that are proposed as examples will be described in detail with reference to the following figures, wherein like numerals reference like elements, and wherein:

FIG. 1 illustrates a perspective view of a heat dissipation module according to some embodiments of the present disclosure.

FIG. 2 illustrates an exploded perspective view of the heat dissipation module shown in FIG. 1.

FIG. 3 illustrates an exploded perspective view of a fan assembly of the heat dissipation module shown in FIG. 1.

FIG. 4 illustrates a perspective view of a fastening member and a stopper of the heat dissipation module shown in FIG. 1.

FIG. 5 illustrates a sectional view of the fan assembly and a securing structure of the heat dissipation module shown in FIG. 1 in a separated state.

FIG. 6 illustrates a sectional view of the heat dissipation module shown in FIG. 1.

### DETAILED DESCRIPTION OF EMBODIMENTS

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

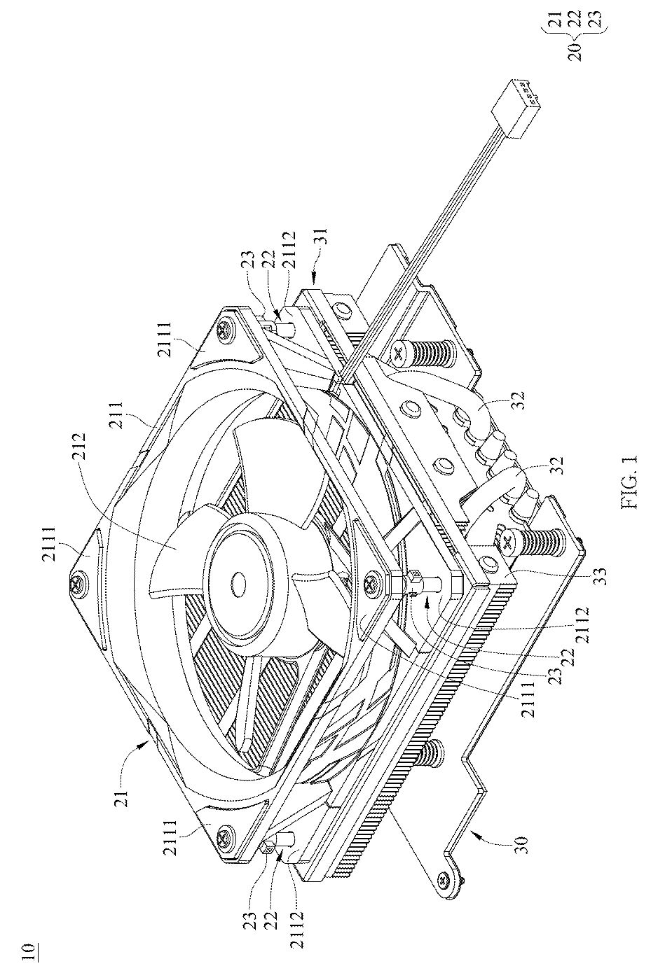

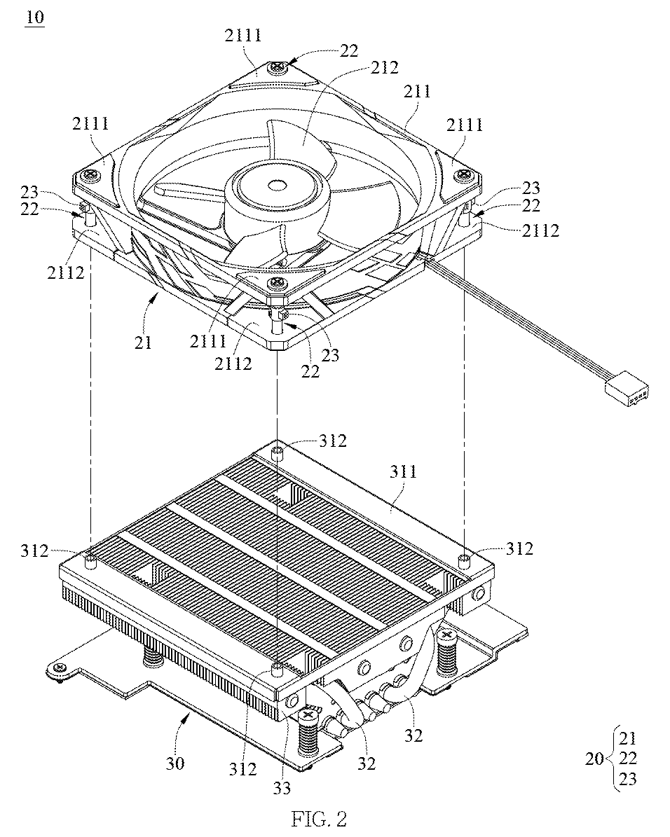

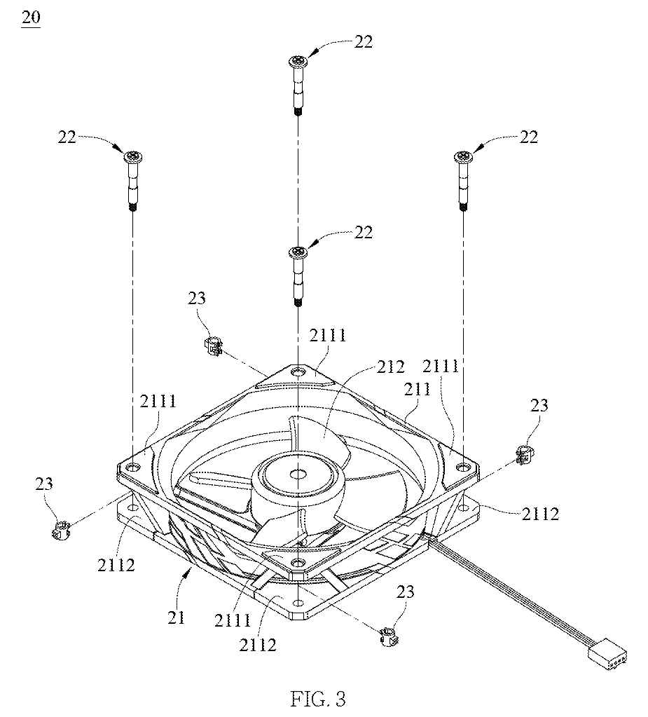

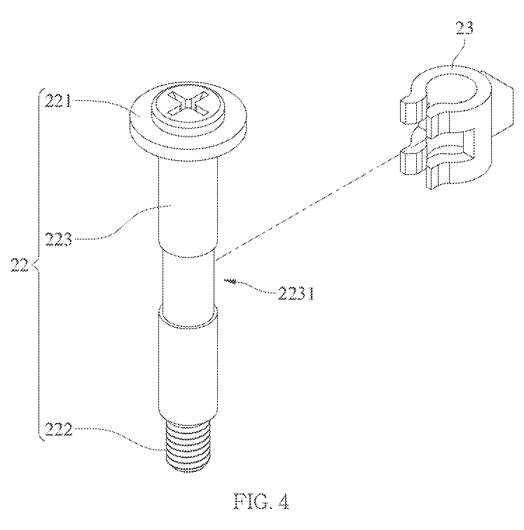

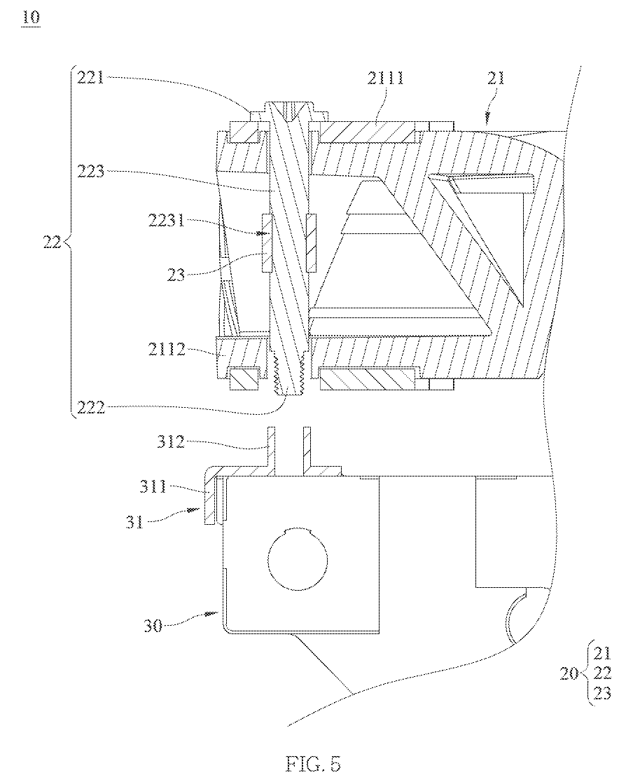

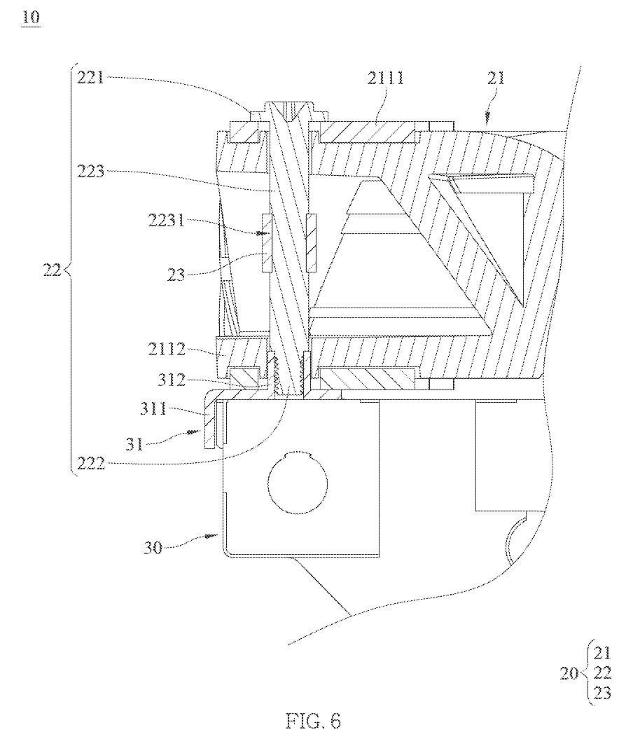

Referring to FIGS. 1-6, FIG. 1 illustrates a perspective view of a heat dissipation module according to some embodiments of the present disclosure. FIG. 2 illustrates an exploded perspective view of the heat dissipation module shown in FIG. 1. FIG. 3 illustrates an exploded perspective view of a fan assembly of the heat dissipation module shown in FIG. 1. FIG. 4 illustrates a perspective view of a fastening member and a stopper of the heat dissipation module shown in FIG. 1. FIG. 5 illustrates a sectional view of the fan assembly and a securing structure of the heat dissipation module shown in FIG. 1 in a separated state. FIG. 6 illustrates a sectional view of the heat dissipation module shown in FIG. 1.

As an example shown in FIG. 1, a heat dissipation module 10 is configured to dissipate heat from a heat source (not shown). The heat dissipation module 10 includes a fan assembly 20 and a securing device 30. The fan assembly 20 includes a fan 21, a plurality of fasteners 22, and a plurality of stoppers 23.

In some embodiments, the fan 21 includes a fan frame 211 and a fan blade 212. The fan blade 212 is rotatably disposed in the fan frame 211. For example, the fan frame 211 may have a rectangular shape. Each of the four corner portions of the fan frame 211 is equipped with a first assembling portions 2111 and a second assembling portions 2112. Each of the first assembling portions 2111 corresponds to the respective second assembling portion 2112, with each corresponding pair arranged along the axial direction of the fan blade 212.

In some embodiments, the fasteners 22 may be screws. Each fastener 22 is inserted movably through the corresponding first assembling portion 2111 and the second assembling portion 2112. Specifically, each fastener 22 includes a head 221, a first fastening portion 222, and a connecting portion 223. The head 221 and the first fastening portion 222 are respectively connected to opposite ends of the connecting portion 223.

In some embodiments, a diameter of the head 221 exceeds that of the first fastening portion 222 and the connecting portion 223. The head 221 abuts against the first assembling portion 2111, while the first fastening portion 222 extends through the second assembling portion 2112. The connecting portion 223 is located at least partially between the first assembling portion 2111 and the second assembling portion 2112.

In some embodiments, each stopper 23 is clamped onto the connecting portion 223 and disposed between the first assembling portion 2111 and the second assembling portion 2112, retaining the fastener 22 within the fan frame 211. Therefore, the stopper 23 is positioned between the first assembling portion 2111 and the second assembling portion 2112, preventing the fastener 22 from detaching from the fan frame 211.

In some embodiments, the connecting portion 223 further includes an assembling groove 2231 disposed between the first assembling portion 2111 and the second assembling portion 2112. Each stopper 23 may be clamped into the assembling groove 2231. Thus, the stopper 23 is positioned and retained in the assembling groove 2231 of the connecting portion 223, preventing it from moving relative to the connecting portion 223.

In some embodiments, the securing device 30 may be a liquid-cooling device, which includes a mounting frame 31, a plurality of heat pipes 32, and a fin set 33. After the first fastening portion 222 passes through the second assembling portion 2112, it may be fastened to the securing device 30.

In some embodiments, the mounting frame 31 is disposed adjacent to the fan frame 211 and includes a frame body 311 and a plurality of second fastening portions 312. Each of the second fastening portions 312 protrudes from the frame body 311 and fits into the fan frame 211. The first fastening portions 222 are secured to the corresponding second fastening portions 312.

In some embodiments, the fin set 33 is disposed on the heat pipes 32, and the heat pipes 32, along with the fin set 33, are positioned on a side of the mounting frame 31 that faces away from the fan frame 211. The incorporation of the liquid-cooling device enables more efficient dissipation of heat generated by the heat source.

In some embodiments, the fasteners 22 remain attached from the fan frame 211 because the fasteners 22 are retained in the fan frame 211 of the fan assembly 20 due to the engagement of the stoppers 23. As a result, when an operator intends to mount the fan assembly 20 to the securing device 30, it is unnecessary to look for extra external fasteners. Instead, the operator can directly use the incorporated fasteners 22 within the fan frame 211 to promptly secure the fan assembly 20 to the securing device 30. In this manner, the assembly efficiency between the fan assembly 20 and the securing device 30 is enhanced.

In some embodiments, the stopper 23 can be properly mounted into the assembling groove 2231 to prevent moving relative to the connecting portion 223. Therefore, when the fastener 22 moves relative to the fan frame 211, the stopper 23 remain attached to the connecting portion 223, preventing the fastener 22 from detaching from the fan frame 211.

In the present disclosure, the first assembling portions 2111, the second assembling portions 2112, the fasteners 22, the stoppers 23, the heat pipes 32, and the second fastening portions 312 are each multiple in number. However, the embodiment is not limited thereto. In other embodiments, each of the aforementioned components may alternatively be provided as a single element.

In the present disclosure, the corner portions of the fan frame 211 are equipped with the first assembling portions 2111 and the second assembling portions 2112. However, the disclosure is not limited thereto. In other embodiments, the first assembling portions and the second assembling portions may be positioned at different locations, such as on the fan frame’s sides.

In the present disclosure, the connecting portion 223 includes the assembling groove 2231, and each stopper 23 is mounted into the assembling groove 2231. However, the disclosure is not limited thereto. In other embodiments, the connecting portion may be formed without an assembling groove, and each stopper may instead be mounted into the connecting portion directly.

In the present disclosure, the securing device 30 is illustrated as a liquid cooling device, as an example. However, the disclosure is not limited thereto. In other embodiments, the securing device 30 may be another type of device, such as a chassis, so long as it is suitable for mounting the fan assembly 20.

According to the present disclosure, the heat dissipation module and fan assembly are designed to enhance assembly efficiency. The fan assembly includes fasteners that are securely held in place by stoppers within the fan frame. As a result, the fasteners do not detach from the fan frame. When securing the fan assembly to the securing device, the operator does not need to utilize separate external fasteners. Therefore, the operator can directly secure the fan assembly to the securing device utilizing the incorporated fasteners, thereby streamlining the assembly process and enhancing efficiency.

Further, because the connecting portion includes the assembling groove and the stopper is mounted into the assembling groove, the stopper is positioned therein to prevent moving relative to the connecting portion. Therefore, when the fastener moves relative to the fan frame, the stopper prevents it from detaching from the connecting portion, thereby preventing the fastener from detaching from the fan frame.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A heat dissipation module, comprising:
a fan assembly, including:
a fan having a fan frame and a fan blade, the fan blade being rotatably disposed in the fan frame, the fan frame including a first assembling portion and a second assembling portion, and both of the first assembling portion and the second assembling portion being arranged along an axial direction of the fan blade;
a fastener movably extending through the first assembling portion and the second assembling portion; and
a stopper disposed on the fastener and located between the first assembling portion and the second assembling portion; and
a securing device, wherein the fastener extends through the first assembling portion and the second assembling portion and is fastened to the securing device.

2. The heat dissipation module of claim 1, wherein the first assembling portion and the second assembling portion are located at corner portions of the fan frame.

3. The heat dissipation module of claim 1, wherein the fastener includes a head, a first fastening portion, and a connecting portion, the head and the first fastening portion being connected to opposite ends of the connecting portion.

4. The heat dissipation module of claim 3, wherein the head has a diameter greater than each of diameters of the first fastening portion and the connecting portion.

5. The heat dissipation module of claim 3, wherein the head abuts against the first assembling portion, and the first fastening portion passes through the second assembling portion to be fastened to the securing device.

6. The heat dissipation module of claim 3, wherein the connecting portion is located at least partially between the first assembling portion and the second assembling portion, and the stopper is mounted into the connecting portion.

7. The heat dissipation module of claim 3, wherein the connecting portion has an assembling groove located between the first assembling portion and the second assembling portion, and the stopper is mounted into the assembling groove.

8. The heat dissipation module of claim 3, wherein the securing device includes a mounting frame, a heat pipe, and a fin set, the mounting frame being disposed adjacent to the fan frame, the first fastening portion being fastened to the mounting frame, the fin set being disposed on the heat pipe, and the heat pipe, along with the fin set, being located on a side of the mounting frame that face away from the fan frame.

9. The heat dissipation module of claim 8, wherein the fin set and the fan assembly are arranged on opposite sides of the mounting frame.

10. The heat dissipation module of claim 3, wherein the stopper surrounds an outer surface of the connecting portion.

11. The heat dissipation module of claim 3, wherein the head of the fastener is positioned on an outer surface of the fan frame.

12. The heat dissipation module of claim 1, wherein the fastener is linearly aligned with the first assembling portion and the second assembling portion along the axial direction of the fan blade.

13. The heat dissipation module of claim 1, wherein the securing device is a liquid cooling device.

14. A fan assembly configured to be installed to a liquid cooling device, the fan assembly comprising:
a fan including a fan frame and a fan blade, the fan blade being rotatably disposed in the fan frame, the fan frame including a first assembling portion and a second assembling portion, and both of the first assembling portion and the second assembling portion being arranged along an axial direction of the fan blade;
a fastener movably extending through the first assembling portion and the second assembling portion; and
a stopper clamped into the fastener and located between the first assembling portion and the second assembling portion to retain the fastener within the fan frame.

15. The fan assembly of claim 14, wherein the first assembling portion and the second assembling portion are located at corner portions of the fan frame.

16. The fan assembly of claim 14, wherein the fastener includes a head, a first fastening portion, and a connecting portion, the head and the first fastening portion being connected to opposite ends of the connecting portion.

17. The fan assembly of claim 16, wherein the head has a diameter greater than each of diameters of the first fastening portion and the connecting portion.

18. The fan assembly of claim 16, wherein the head abuts against the first assembling portion, and the first fastening portion passes through the second assembling portion to be fastened to the liquid cooling device.

19. The fan assembly of claim 16, wherein the connecting portion is located at least partially between the first assembling portion and the second assembling portion, and the stopper is mounted into the connecting portion.

20. The fan assembly of claim 16, wherein the connecting portion has an assembling groove located between the first assembling portion and the second assembling portion, and the stopper is mounted into the assembling groove.
